(19) United States
(12) Patent Application Publication
(10) Pub. No.: US 2024/0222329 A1
(43) Pub. Date: Jul. 4, 2024

(54) STACKED PACKAGE, METHOD OF MAKING AND ELECTRONIC DEVICE INCLUDING THE STACKED PACKAGE

(71) Applicant: Yibu Semiconductor Co., Ltd., Shanghai (CN)

(72) Inventor: Ming Li, Fremont, CA (US)

(73) Assignee: Yibu Semiconductor Co., Ltd., Shanghai (CN)

(21) Appl. No.: 18/401,325

(22) Filed: Dec. 29, 2023

(30) Foreign Application Priority Data
Dec. 29, 2022 (CN) 202211707002.5
Dec. 29, 2022 (CN) 202211707058.0

(51) Int. Cl. H01L 25/065; H01L 21/56; H01L 23/00; H01L 23/31; H01L 23/528; H01L 25/00

(52) U.S. Cl. CPC H01L 25/0657; H01L 21/568; H01L 23/3107; H01L 23/528; H01L 24/16; H01L 25/50; H01L 2224/16145

(57) ABSTRACT

The present disclosure relates to a package-on-package, a method of forming and an electronic device including the same. The package-on-package includes at least two pre-packages; each pre-package at least comprises a chip, a first redistribution layer and first connectors; the at least two pre-packages are stacked and interconnected, with the active surface of one pre-package in any two adjacent pre-packages facing the passive surface of the other pre-package, and the first connectors of one pre-package electrically connected with the first redistribution layer of the other pre-package. The first redistribution layer is positioned on an active surface of the chip, the first connectors and the chip are positioned on the same side of the first redistribution layer, and at least some of the first connectors are located on at least one edge side of the chip. Therefore, the stacking/interconnecting of the chip is realized through the first connectors and the first redistribution layer. Compared with the related technology, the length of the electric interconnection is shortened, the electric performance is higher, and through vias are not needed, resulting in lower manufacturing cost.

### CROSS REFERENCE TO RELATED APPLICATION

This application claims the benefit of priority under the Paris Convention to Chinese Patent Application No. 202211707002.5A, filed on Dec. 29, 2022, Chinese Patent Application No. 202211707058.0A, filed on Dec. 29, 2022, each of which is incorporated herein by reference in its entirety. This application is related to co-pending U.S. patent application entitled “Fan-out stacked package, method of making and electronic device including the stacked package,” filed on even date herewith, which is incorporated herein by reference in its entirety.

### FIELD

The present disclosure relates to the field of semiconductor technologies, and in particular, to a stacked package, a method for making the stacked package, and an electronic device including the stacked package.

### BACKGROUND

In the field of logic circuits and memory integration, Package-on-package (POP) has become the first choice in the industry and is mainly used to manufacture high-end portable devices and advanced mobile communication platforms used in smartphones. Low-power memory packaging is composed of multiple memory chips stacked and interconnected through wire bonding (WB). It is mainly used in the upper layer of the package stack in smartphones, or directly soldered to the motherboard of a host computer of a laptop using Wire Bonding (WB) as an interconnection.

Among related technologies, the Low Power memory storage technology is the fifth generation Low Power consumption dual Data Rate memory standard (Low Power Double Data Rate 5×, lpddr 5×), and the maximum memory speed is 8.5 Gbps; in the future sixth generation of Low Power consumption dual Data Rate memory standards (Low Power Double Data Rate 6×, lpddr 6×), the maximum memory speed is expected to be 17.0 Gbps, and at the high-speed operation speed of the 17.0 Gbps memory, the interconnection using wire bonding as the memory stack is not sustainable due to the consideration of Signal Integrity (SI) and Power Integrity (PI), and the metal lead wire has a long length and a small diameter, so the resistance is high, which results in poor electrical performance, easy Signal distortion and long transmission time; through-Silicon-Via (TSV) technology reduces interconnection length and signal delay Through vertical interconnection, has good electrical performance, reduces capacitance/inductance, realizes low power consumption and high-speed communication between chips, has greater space efficiency and higher interconnection density, but has higher process cost.

Also, in the field of computer servers, with the increase of computing power, the demand for Memory capacity is higher and higher, and a Fourth/Fifth Generation Double Data Rate Synchronous Dynamic Random Accepackage-on-packageMemory (DDR 4/5 SDRAM) stack is a path for solving the demand for Memory capacity, and there are two schemes: the DDR4/5 memory storage package is formed by stacking a plurality of storage chips and is used as interconnection through wire bonding; the DDR4/5 memory storage package is formed by stacking a plurality of storage chips and is interconnected through a silicon through hole technology. The two schemes also have the technical problems that the wire bonding has poor electrical performance, and the through silicon via has high procepackage-on-packagecost.

### SUMMARY

In order to solve the technical problems or at least partially solve the technical problems, the present disclosure provides a package-on-package (or a stacked package), a method the same, and an electronic device.

In a first aspect, the present disclosure provides a package-on-package comprising at least two pre-packages; each pre-package at least comprising a chip, a first redistribution layer and first connectors. In some embodiments, the at least two pre-packages are stacked and interconnected, the active surface of one pre-package in the two adjacent pre-packages is facing the passive surface of the other pre-package, and the first connectors of one pre-package are electrically connected with the first redistribution layer of the other pre-package.

In some embodiments, in the stacking/interconnecting direction, the first redistribution layer is positioned on one side of an active surface of the chip, and the first connectors and the chip are positioned on the same side of the first redistribution layer; in any direction perpendicular to the stacking/interconnecting direction, at least some of the first connectors are located on at least one side of a chip, and each first connector is electrically connected with the chip through the first redistribution layer.

In some embodiments, the pre-package further comprises a encapsulation layer that encapsulates the chip and the first connectors, and a first connector includes a first conductive post (or column), and the first conductor columns extend through the pre-encapsulation layer and is connected with the first redistribution layer of the pre-package.

In some embodiments, a first connector further comprises a metal bump, the metal bump is electrically connected with the first conductor columns and exposed outside the surface of the pre-encapsulation layer, and the metal bump is electrically connected with the first redistribution layer of the adjacent pre-package.

In some embodiments, the pre-package body for external connection further includes a second redistribution layer and second connectors, the second redistribution layer is located on one side, away from the first redistribution layer, of the chip and one side, away from the first connectors, the second connectors is located on one side, away from the chip and one side, away from the first connectors, of the second redistribution layer, the second redistribution layer is electrically connected with the first connectors and the second connectors, and the second connectors are used for externally connecting other components.

In some embodiments, the package-on-package further includes a substrate and an encapsulation layer; the substrate is positioned on one side, away from the second redistribution layer, of the second connector; in a first preset direction, the length of the substrate is greater than that of the pre-package; the first preset direction is any direction perpendicular to the stacking/interconnecting direction; the encapsulation layer is positioned on one side of the substrate facing the pre-package, and the encapsulation layer covers all the pre-packages which are connected in a stacked mode and the surface of the substrate facing the pre-packages.

In some embodiments, the second connectors comprises a second conductive post and a solder bump, the second conductive post and the solder bump being electrically connected; the second conductor pillar is located on one side of the second redistribution layer, which is away from the chip and the first connectors, and is electrically connected with the second redistribution layer; the welding block is positioned on one side of the second conductor columns away from the second redistribution layer, and used for connecting the substrate.

In some embodiments, the package-on-package further comprises third connectors; the third connectors are positioned on one side of the substrate, which faces away from the second connectors, and is used for connecting other components.

In some embodiments, the pre-package further comprises bonding pads; the bonding pads are located on one side of the active surface of the chip, the bonding pads are distributed in an area of the chip close to the first connectors, and the bonding pads are electrically connected with the first connectors through the first redistribution layer.

In some embodiments, the chip comprises at least one of a memory chip, a computing chip, a communication chip, a sensing chip and a power chip.

In some embodiments, the arrangement positions of the first connectors in two adjacent pre-packages correspond with each other.

In a second aspect, the present disclosure also provides a method for manufacturing a package-on-package, including forming at least two pre-packages; each pre-package at least comprises a chip, a first redistribution layer and first connectors; interconnecting the at least two pre-package stacks, wherein an active surface of one pre-package in two adjacent pre-packages is opposite to a passive surface of the other pre-package, and each first connector of one pre-package is electrically connected with a first redistribution layer of the other pre-package; in the stacking/interconnecting direction, the first redistribution layer is positioned on one side of an active surface of the chip, and the first connectors and the chip are positioned on the same side of the first redistribution layer; in any direction perpendicular to the stacking/interconnecting direction, at least some of the first connectors are located on at least one edge side of the chip and is electrically connected with the chip through the first redistribution layer.

In some embodiments, forming the pre-package comprises:
providing a first carrier plate;
forming a first conductor pillar on one side of the first carrier plate;
providing at least one chip;
attaching the active surface of the chip to the first carrier plate; the chip and the first conductive columns are positioned on the same side of the first carrier plate;
forming a pre-encapsulation layer, wherein the pre-encapsulation layer coats the chip, the first conductor pillar and the surface of the first carrier plate facing the chip and the first conductor pillar, and the first conductor pillar is filled in and penetrates through the pre-encapsulation layer;
providing a second carrier plate and attaching the second carrier plate to one side of the pre-encapsulation layer, which is away from the first carrier plate;
removing the first carrier plate, and forming a first redistribution layer on the chip and one side, away from the second carrier plate, of the first conductor pillar;
providing a third carrier plate and attaching the third carrier plate to one side of the first redistribution layer, which is away from the chip and the first conductive post; and
removing the second carrier plate, and forming a metal bump on one side of the first conductor pillar, which is away from the third carrier plate.

In some embodiments, forming a pre-package for external connection includes:
executing the step of forming the pre-package until the second carrier plate is removed;
forming a second redistribution layer on the chip and one side, away from the third carrier plate, of the first conductor column; and
forming second connectors on one side of the second redistribution layer, which is away from the chip and the first conductor pillar.

In some embodiments, after the interconnecting and stacking the at least two pre-packages, the method of making a stacked package further comprises:
connecting a substrate on one side of the second connectors facing away from the second redistribution layer; wherein, in a first preset direction, the length of the substrate is greater than that of the pre-package; the first preset direction is any direction perpendicular to the stacking/interconnecting direction; and
forming an encapsulation layer on one side of the substrate facing the pre-encapsulation body; wherein the encapsulation layer covers all the pre-packages and the surface of the substrate facing the pre-packages, which are connected in a stacked mode.

In a third aspect, the present disclosure also provides an electronic device, including: any of the above stacked packages.

The present disclosure provides a stack package, a method for manufacturing the same, and an electronic device, the stack package including: at least two pre-packages each pre-package at least comprising a chip; a first redistribution layer and first connectors. In some embodiments. the at least two pre-packages are stacked and interconnected, the active surface of one pre-package in the two adjacent pre-packages is opposite to the passive surface of the other pre-package, and the first connectors of one pre-package are electrically connected with the first redistribution layer of the other pre-package. In some embodiments, in the stacking/interconnecting direction, the first redistribution layer is positioned on one side of the active surface of the chip, and the first connectors and the chip are positioned on the same side of the first redistribution layer. In any of one or more directions perpendicular to the stacking/interconnecting direction, at least one first connector may be located on at least one edge side of the chip, and each first connector is electrically connected with the chip through the first redistribution layer. Therefore, compared with the prior art, the technical scheme provided by the disclosure has various advantages. Since the first connectors and the first redistribution layer are used to realize the stacking/interconnecting of the chip, compared with a lead bonding technology, the length of the electric interconnection is shortened, the electric performance is higher, and the connection reliability and the signal transmission speed are improved. Compared with the through silicon via technology, the procepackage-on-packagecost is lower because there is no need for forming through silicon vias.

### BRIEF DESCRIPTION OF THE DRAWINGS

The accompanying drawings, which are incorporated in and constitute a part of this specification, illustrate embodiments consistent with the disclosure and together with the description, serve to explain the principles of the disclosure.

In order to more clearly illustrate the embodiments of the present disclosure or the solutions in the prior art, the drawings that are required for the description of the embodiments or the prior art will be briefly described below, and it would be obvious to those skilled in the art to obtain other drawings from these drawings without inventive effort.

FIG. 1 is a schematic structural diagram of a package-on-package according to an embodiment of the disclosure.

FIG. 2 is a schematic structural diagram of another package-on-package provided in the embodiment of the present disclosure.

FIG. 3 is a schematic structural diagram of a pre-package according to an embodiment of the disclosure.

FIG. 4 is a schematic structural diagram of another pre-package according to an embodiment of the disclosure.

FIG. 5 is a schematic structural diagram of a pre-package for external connection according to an embodiment of the disclosure.

FIG. 6 is a schematic structural diagram of another pre-package for external connection according to an embodiment of the present disclosure.

FIG. 7 is a schematic structural diagram of another pre-packaged body according to an embodiment of the present disclosure.

FIG. 8 is a schematic structural diagram of another pre-packaged body according to an embodiment of the present disclosure.

FIG. 9 is a schematic structural diagram of another pre-packaged body according to an embodiment of the present disclosure.

FIG. 10 is a schematic structural diagram of another pre-packaged body according to an embodiment of the present disclosure.

FIG. 11 is a schematic structural diagram of another pre-packaged body according to an embodiment of the present disclosure.

FIG. 12 is a schematic structural diagram of another pre-packaged body according to an embodiment of the present disclosure.

FIG. 13 is a schematic flow chart illustrating a method for manufacturing a package-on-package according to an embodiment of the disclosure.

FIG. 14 is a schematic view of a detailed flow of “forming a pre-package” provided in an embodiment of the present disclosure.

FIG. 15 is a schematic structural diagram corresponding to each step of “forming a pre-package”.

FIG. 16 is a schematic diagram of a detailed flow of forming a pre-package for external connection according to an embodiment of the present disclosure.

FIG. 17 is a schematic structural diagram corresponding to each step of “forming a pre-package for external connection”.

FIG. 18 is a schematic flow chart of another method for manufacturing a package-on-package according to an embodiment of the disclosure.

### DETAILED DESCRIPTION OF THE EMBODIMENTS

In order that the above objects, features and advantages of the present disclosure may be more clearly understood, a further description of aspects of the present disclosure will be provided below. It should be noted that, without conflict, the embodiments of the present disclosure and features in the embodiments may be combined with each other.

In the following description, numerous specific details are set forth in order to provide a thorough understanding of the present disclosure, but the present disclosure may be practiced otherwise than as described herein. it will be apparent that the embodiments in the specification are only some, but not all, embodiments of the disclosure.

To addrepackage-on-package the problems raised in the background section, embodiments of the present disclosure provide a package-on-package, a method for manufacturing the same, and an electronic device, where the package-on-package includes: at least two pre-packages; each pre-package comprises a chip, a first redistribution layer and first connectors. The at least two pre-packages are stacked and interconnected, the active surface of one pre-package in the two adjacent pre-packages is opposite to (e.g., facing) the passive surface of the other pre-package, and the first connectors of one pre-package are electrically connected with the first redistribution layer of the other pre-package. In some embodiments, in the stacking/interconnecting direction, the first redistribution layer is positioned on one side of the active surface of the chip, and the first connectors and the chip are positioned on the same side of the first redistribution layer; in any of one or more directions perpendicular to the stacking/interconnecting direction, at least some of the first connectors are located on at least one edge side of the chip, and each first connector is electrically connected with the chip through the first redistribution layer. Therefore, the first connectors and the first redistribution layer are used to realize the stacking/interconnecting of the chip. Compared with a lead bonding technology, the length of the electric interconnection is shortened, the electric performance is higher, and the connection reliability and the signal transmission speed are improved. Compared with the through silicon via technology, the process cost is lower because no perforated through silicon vias need to be formed.

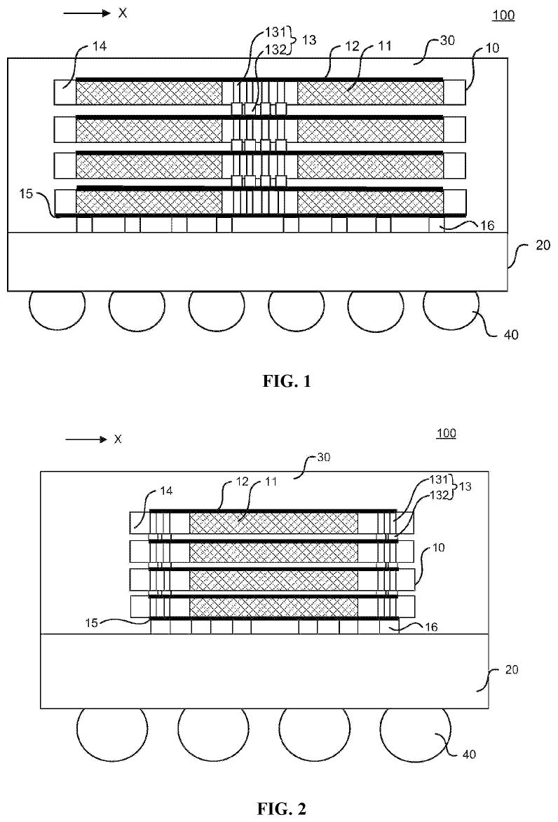

The stacked package, the method for manufacturing the stacked package, and the electronic device provided by the embodiments of the present disclosure are described below with reference to FIGS. 1 to 18.

An embodiment of the present disclosure provides a package-on-package, as shown in FIGS. 1-2, FIG. 1 is a schematic structural diagram of a package-on-package provided in an embodiment of the present disclosure, and FIG. 2 is a schematic structural diagram of another package-on-package provided in an embodiment of the present disclosure. Referring to FIGS. 1-2, the package-on-package 100 includes at least two pre-packages 10. Each pre-package body 10 includes at least a chip 11, a first redistribution layer 12, and first connectors 13; at least two pre-packages 10 are connected in a stacked mode, the active surface of one pre-package 10 in every two adjacent pre-packages 10 is opposite to (e.g., facing) the passive surface of the other pre-package 10, and the first connectors 13 of one pre-package 10 are electrically connected with the first redistribution layer 12 of the other pre-package 10. In some embodiments, in the stacking/interconnecting direction, the first redistribution layer 12 is located on the active surface side of the chip 11, and the first connectors 13 and the chip 11 are located on the same side of the first redistribution layer 12. In some embodiments, in any of one or more directions perpendicular to the stacking/interconnecting direction (e.g., a first predetermined direction X in the figure), at least some of the first connectors 13 are located on at least one edge side of the chip 11 and is electrically connected to the chip 11 through the first redistribution layer 12.

The chip 11 includes, but is not limited to, a Memory chip, a computing chip, a sensing chip, a communication chip, a sensing chip, and a power chip, including, for example, a Dynamic Random Access Memory (DRAM) chip or a Double Data Rate Dynamic Random Access Memory (DDR DRAM).

The first redistribution layer 12 includes a metal thin film layer that can be prepared by electroplating or deposition of a metal material, which can be at least one of copper, aluminum, silver, gold and titanium.

The height of the first connectors 13 in the stacking interconnection direction is equal to or greater than that of the chip 11, and the arrangement is such that the first connectors 13 of the pre-package 10 located on the upper layer can be in contact with the first redistribution layer 12 of the pre-package 10 located on the lower layer, thereby ensuring reliable connection. Each first connector 13 may include a metal column or a metal block formed by a metal material, such as a copper column, an aluminum column, a silver column, and the like, or may be a column body formed by other conductive materials, which is not limited herein.

The first connectors 13 and the first redistribution layer 12 may include the same material, or may include different materials, which is not limited herein.

Illustratively, as shown in FIG. 1, the package-on-package (or stacked package) 100 includes four pre-packages 10, each pre-package 10 including two chips 11, a first redistribution layer 12, and first connectors 13. The active surface of the chip 11 is electrically connected with the first redistribution layer 12 in the first preset direction X, the first connectors 13 are located on one edge side of the chip 11 and is electrically connected with the chip 11 through the first redistribution layer 12. In some embodiments, the first connections 13 are distributed over the area between the two chips 11. In the stacking/interconnecting direction, the first connectors 13 of the upper pre-package 10 of the two adjacent pre-packages 10 is electrically connected to the first redistribution layer 12 of the lower pre-package 10, one side of the chip 11 in the pre-package 10 facing the first redistribution layer 12 is an active surface, and one side facing away from the redistribution layer is a passive surface, so that the passive surface of the upper pre-package 10 is opposite to the active surface of the lower pre-package 10.

Illustratively, as shown in FIG. 2, the package-on-package 100 includes four pre-packages 10, each pre-package 10 includes one chip 11, a first redistribution layer 12, and first connectors 13; the active surface of the chip 11 is electrically connected with the first redistribution layer 12, in the first preset direction X, the first connecting bodies 13 are located on two sides of the chip 11, and the first connecting bodies 13 are electrically connected with the chip 11 through the first redistribution layer 12; the first connections 13 are distributed in both side regions of the chip 11. In the stacking/interconnecting direction, the first connectors 13 of the upper pre-package 10 of the two adjacent pre-packages 10 is electrically connected to the first redistribution layer 12 of the lower pre-package 10, one side of the chip 11 in the pre-package 10 facing the first redistribution layer 12 is an active surface, and one side facing away from the redistribution layer is a passive surface, so that the passive surface of the upper pre-package 10 is opposite to the active surface of the lower pre-package 10.

Each first connector 13 of the upper pre-package 10 is electrically connected to the first redistribution layer 12 of the lower pre-package 10, and can be connected by any metal connection process known to those skilled in the art, such as pressure welding, arc welding, argon arc welding, gas shielded arc welding, and laser welding, but not limited thereto.

It should be noted that FIG. 1-2 only exemplarily show that the stacked package 100 includes four pre-packages 10, each pre-package 10 in FIG. 1 includes two chips 11 and the first connectors 13 are distributed in the region between the two chips 11; each pre-package 10 in FIG. 2 includes a chip 11 and first connectors 13 distributed on two sides of the chip 11, but the above does not limit the stacked package provided by the embodiments of the present disclosure. In other embodiments, the number of the pre-packages 10, the number of the chips 11 in each pre-package 10, and the distribution area of the first connectors 13 may be set according to the requirement of the stacked package, which is not limited herein.

The embodiment of the present disclosure provides a package-on-package 100, including: at least two pre-packages 10; each pre-package body at least comprises a chip 11, a first redistribution layer 12 and first connectors 13; at least two pre-packages 10 are connected in a stacked mode, the active surface of one pre-package 10 in every two adjacent pre-packages 10 is opposite to the passive surface of the other pre-package 10, and each first connector 13 of one pre-package 10 is electrically connected with the first redistribution layer 12 of the other pre-package 10; in the stacking/interconnecting direction, the first redistribution layer 12 is located on the active surface side of the chip 11, and the first connectors 13 and the chip 11 are located on the same side of the first redistribution layer 12; in any of one or more directions perpendicular to the stacking/interconnecting direction, the first connectors 13 are located on one edge side of the chip 11 and is electrically connected to the chip 11 through the first redistribution layer 12. Therefore, the stacking/interconnecting of the chip 11 is realized through the first connectors 13 and the first redistribution layer 12, compared with the wire bonding technology, the length of the electrical interconnection is shortened, the electrical performance is higher, and the connection reliability and the signal transmission speed are improved; compared with the through silicon via technology, the through silicon via technology does not need to be perforated, and the process cost is lower.

In some embodiments, as shown in FIGS. 1 to 6, FIG. 3 is a schematic structural diagram of a pre-package provided in an embodiment of the present disclosure, FIG. 4 is a schematic structural diagram of another pre-package provided in an embodiment of the present disclosure, FIG. 5 is a schematic structural diagram of a pre-package for external connection provided in an embodiment of the present disclosure, and FIG. 6 is a schematic structural diagram of another pre-package for external connection provided in an embodiment of the present disclosure. Referring to FIG. 1-6, the pre-package 10 further includes: the pre-encapsulation layer 14, wherein the chip 11 and the first connectors 13 are embedded in the pre-encapsulation layer 14; each first connector 13 includes a first conductive post 131; the first conductor pillar 131 extends through the encapsulation layer 14, connecting the first redistribution layer 12 of the pre-package 10.

The pre-encapsulation layer 14 may be provided as a resin layer, and the material may be one or a combination of Epoxy resin (EMC), polyethylene, polypropylene, polyolefin, polyamide, polyurethane, or the like. The pre-encapsulation layer 14 covers the chip 11 and the first connectors 13 and the surface of the first redistribution layer 12 facing the chip 11 and the first connectors 13, and fills the gap between the chip 11 and the first connectors 13; the surface of the first redistribution layer 12 facing away from the chip 11 and the first connectors 13 is exposed at the surface of the pre-encapsulation layer 14, and the surface of the first redistribution layer 12 facing away from the chip 11 and the first connectors 13 may be flush with or protrude from the surface of the pre-encapsulation layer 14.

The first conductive column (or pillar) 131 of a first connector 13 is located in the encapsulation layer 14 and penetrates through the encapsulation layer 14, and one end of the first conductive pillar 131 is connected to the first redistribution layer of the pre-package.

In some embodiments, as shown in FIG. 1-4, a first connector 13 further comprises: a metal bump 132; the metal bump 132 is electrically connected to the first conductive pillar 131 and exposed outside the surface of the encapsulation layer 14; the metal bump 132 is electrically connected to the first redistribution layer 12 of the adjacent pre-package 10.

The metal bump 132 is electrically connected to one end of the first conductive pillar 131 away from the first redistribution layer 12, protrudes from a surface of the encapsulation layer 14 away from the first redistribution layer 12, and is electrically connected to the first redistribution layer 12 of the adjacent pre-package 10. The first conductive pillar 131 and the metal bump 132 may be made of the same metal material, or may be made of different metal materials, which is not limited herein.

For example, as shown in FIG. 1-2, the pre-packages are applied to the 1 st to 3 rd pre-packages, i.e. the pre-packages except the bottommost pre-package in the stacked package, in order from top to bottom; in the first preset direction X, the length of the metal bump 132 is greater than that of the first conductor pillar 131, so that the contact area between the metal bump 132 and the first redistribution layer 12 of the adjacent pre-package is increased, the connection reliability is improved, and the connection process difficulty is reduced; the first preset direction is any of one or more directions perpendicular to the stacking/interconnecting direction.

In some embodiments, a first connector 13 further includes a solder bump, the solder bump is located at an end of the metal bump 132 away from the first conductive pillar 131 and is formed as a hat bump, and the solder bump is made of a conductive metal, such as tin.

In some embodiments, as shown in FIGS. 1-2 and 5-6, the pre-package 10 for external connection further includes a second redistribution layer 15 and second connectors 16; the second redistribution layer 15 is located on one side of the chip 11 and the first connectors 13, which is away from the first redistribution layer 12, the second connectors 16 are located on one side of the second redistribution layer 15, which is away from the chip 11 and the first connectors 13, the second redistribution layer 15 is electrically connected with the first connectors 13 and the second connectors 16, and the second connectors 16 are used for externally connecting other components.

The pre-package 10 for external connection is the pre-package 10 located at the bottommost portion of the stacked package in the stacking interconnection direction, and the rest of the packages 10 are stacked above the pre-package 10; the side of the pre-package 10 facing away from the remaining pre-packages 10 is sequentially provided with a second redistribution layer 15 and a second connector 16, where the second connectors 16 are used for externally connecting other components, such as a substrate, a Printed Circuit Board (PCB) or a processor, and the processor may be a Central Processing Unit (CPU) or other Processing Unit with data Processing capability and/or instruction execution capability.

Since the bottom of the pre-package 10 for external connection is no longer connected to other pre-packages 10 in a stacked manner, the first connector 13 of the pre-package 10 for external connection only includes the first conductive pillar 131 penetrating through the encapsulation layer 14, and the metal bump 132 is no longer provided; a second redistribution layer 15 is formed on the side of the pre-package 10 for external connection, which is away from the first redistribution layer 12, the first connectors 13 are electrically connected with the second redistribution layer 15, the second redistribution layer 15 is electrically connected with the second connectors 16, and all the pre-packages 10 in the stacked package 100 are interconnected with a base (such as a substrate, a PCB or a CPU) through the first connectors 13, the second redistribution layer 15 and the second connectors 16.

The second redistribution layer 15 is a metal thin film layer and can be prepared by an electroplating or deposition process; the metal material can be at least one of copper, aluminum, silver, gold and titanium.

The size of a second connector 16 is larger than that of a first connector 13, namely, the contact area between the second connectors 16 and the second redistribution layer and between the second connectors and the external connection component is increased, so that the firmness of connection is enhanced, the connection reliability and the signal transmission are improved, and meanwhile, the size of the second connectors 16 are increased, and the difficulty of the connection process is reduced. The second connectors 16 are arranged in a column shape, a block shape or a sphere shape, and the material thereof is a conductive material, including a metal material (at least one of copper, aluminum, silver, gold and titanium) and a conductive non-metal material. The number and arrangement of the second connecting bodies 16 need to be flexibly set according to the external connection components, and are not limited herein.

In some embodiments, as shown in FIG. 1-2, the package-on-package 100 further comprises: a substrate 20 and an encapsulation layer 30; the substrate 20 is located on the side of the second connectors 16 away from the second redistribution layer 15; in the first preset direction X, the length of the substrate 20 is greater than the length of the pre-package 10; the first preset direction X can be any direction perpendicular to the stacking/interconnecting direction; the encapsulation layer 30 is located on the side of the substrate 20 facing the pre-package 10, and the encapsulation layer 30 covers all the pre-packages 10 and the surface of the substrate 20 facing the pre-package 10.

Wherein, the substrate 20 is made by pressing at least one of Ajinomoto built-up Film (ABF) and Bismaleimide sulfide/Triazon resin (BT) through a plate pressing process; the substrate 20 is provided with a through hole penetrating the thickness thereof, and the through hole is filled with a conductor material, so that components on both sides of the substrate 20 are electrically connected. The substrate 20 serves as a substrate for the encapsulation layer 30, and provides support for the encapsulation layer 30, so that the length of the substrate 20 in the first predetermined direction X is greater than the length of the pre-package 10. The encapsulation layer 30 may be a prepreg, which includes one or a combination of epoxy resin, polyethylene, polypropylene, polyolefin, polyamide, polyurethane, and the like, and covers the entire surface of the pre-encapsulation 10 and the surface of the substrate 20 facing the pre-encapsulation 10. The encapsulating layer 30 may also be made of liquid or powdered epoxy resin, which not only covers all surfaces of the pre-package 10 and the substrate 20 facing the pre-package 10, but also fills all gaps between the pre-packages 10 and between the pre-package 10 and the substrate 20.

With such an arrangement, the stacked package 100 is protected from being damaged by external factors (such as liquid and metal), and all the pre-packages are fixed to prevent the pre-packages from moving to disconnect the connection circuit.

In some embodiments, as shown in FIG. 5-6, a second connector 16 includes a second conductive post 161 and a solder bump 162, the second conductive post 161 and the solder bump 162 being electrically connected; the second conductive post 161 is located on a side of the second redistribution layer 15 away from the chip 11 and the first connectors 13, and is electrically connected to the second redistribution layer 15; a solder bump 162 is located on a side of the second conductive post 161 facing away from the second redistribution layer 15 for connection to the substrate 20.

The second conductive pillar 161 is a metal pillar made of a metal material, such as a copper pillar, an aluminum pillar, and a silver pillar, and may also be a pillar made of another conductive material, which is not limited herein. The solder bump 162 is located on a layer of the second conductive post 161 facing away from the second redistribution layer 15, and is a hat bump. Illustratively, the second conductor pillar 161 is configured as a copper pillar, and the solder bump 162 is configured as a solder cap, and the electrical connection between the pre-package 10 and the substrate is realized through a soldering process.

In some embodiments, as shown in FIG. 1-2, the package-on-package 100 further comprises: third connectors 40; the third connectors 40 are located on a side of the substrate 20 away from the second connectors 16 for connecting other components.

Wherein the third connectors 40 and the second connectors 16 are electrically connected by the conductor material filled in the through hole of the substrate 20. The conductor material comprises a metal material such as copper, aluminum, silver, gold and titanium or a conductive non-metal material.

The third connectors 40 are provided in a column shape, a block shape or a sphere shape, and the material thereof is a conductive material, including a metal material (at least one of copper, aluminum, silver, gold and titanium) and a conductive non-metal material. The number and arrangement of the third connecting bodies 40 need to be flexibly set according to the externally connected components, and are not limited herein.

In some embodiments, as shown in FIGS. 8 to 11, there is provided a schematic structural diagram of another kind of pre-package according to embodiments of the present disclosure. Referring to FIG. 8-11, the pre-package further comprises: bonding pads 17; the bonding pads 17 are located on the active surface side of the chip 11, the bonding pads 17 are distributed in a region of the chip 11 close to the first connectors 13, and the bonding pads 17 are electrically connected to the first connectors 13 through the first redistribution layer 12.

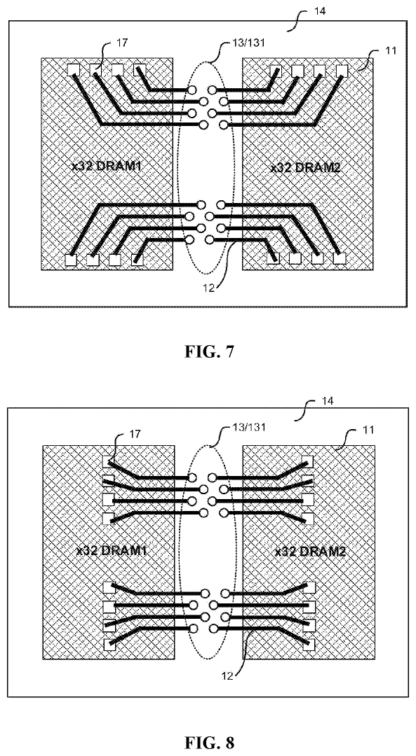

Bond pads 17 are typically located at the edge of chip 11 (as shown in FIG. 7) in the prior art, which, if applied to the present disclosure, reduces the vertical interconnect length between encapsulation layers; however, since the arrangement direction of the bonding pads 17 is perpendicular to the overall arrangement direction of the first connectors 13, there is a problem that the length of the first redistribution layer 12 is long, and the scheme can be further optimized by adjusting the distribution positions of the bonding pads 17. The distribution positions of the bonding pads 17 are set according to the distribution positions of the first connecting bodies 13, and the bonding pads 17 are distributed in an area of the chip 11 close to the first connectors 13, so that the length of the first redistribution layer 12 is shortened, namely the electrical interconnection length is shortened, the capacitance and the inductance are reduced, and the electrical performance is further improved.

Exemplarily, as shown in FIG. 8, the first connectors 13 are distributed in the gap between the two chips 11; the bonding pads 17 are positioned in the middle area of the chip and are arranged along the parallel direction of the two chips 11; with this arrangement, the length of the first redistribution layer 12 is shortened.

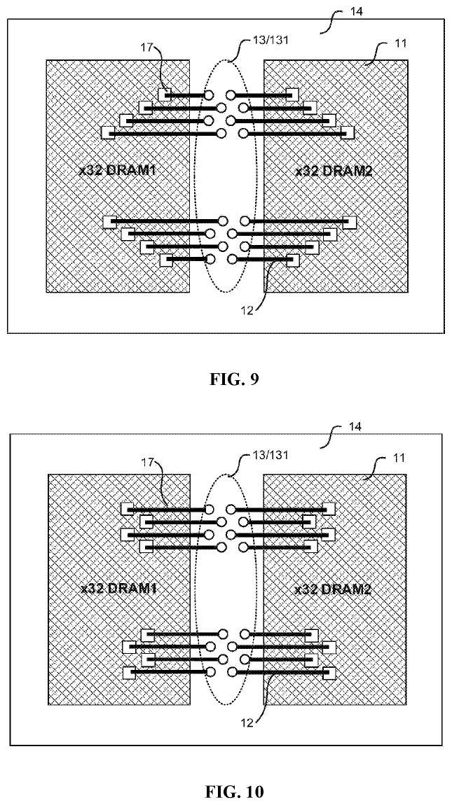

Exemplarily, as shown in FIG. 9, the first connection bodies 13 are distributed in the gap between the two chips 11; the bonding pads 17 are located in the middle region of the chip, and gradually approach the first connectors from inside to outside along the parallel direction of the two chips 11, and the length of the first redistribution layer 12 is gradually shortened.

Exemplarily, as shown in FIG. 10, the first connection bodies 13 are distributed in the gap between the two chips 11; the bonding pads 17 are located in the middle region of the chip and are arranged in the parallel direction of the two chips 11 as a whole, and the bonding pads 17 are not aligned, so that the length of the first redistribution layer 12 is also shortened.

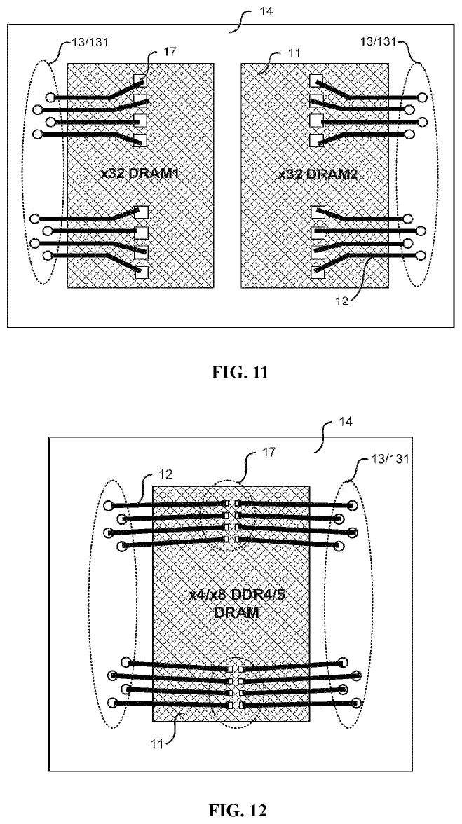

Exemplarily, as shown in FIG. 11, the first connection bodies 13 are distributed outside the chip 11; the bonding pads 17 are positioned in the middle area of the chip and are arranged along the parallel direction of the two chips 11; with this arrangement, the length of the first redistribution layer 12 is shortened.

Taking the pre-packages shown in FIG. 7-11 as an example, each pre-package includes two 32-bit Dynamic Random Access Memories (DRAMs), and the number of bonding pads 17, the number of first redistribution layers 12, and the number of first connectors 13 (i.e., first conductor pillars 131) disposed on the active surface of the chip 11 are all equal, which requires about 400; the diameter of the first conductor columns 131 is greater than or equal to 25 μm, and the pitch is greater than or equal to 40 μm; the minimum line width/pitch of the first redistribution layer 12 is 5 μm.

It can be understood that FIG. 8-11 only exemplarily show the distribution positions of the bonding pads 17 on the active surface side of the chip 11 and the number of the bonding pads 17 is 8, but do not constitute a limitation of the stacked package provided by the embodiment of the present disclosure. In other embodiments, the distribution position and the number of the bonding pads may be flexibly set according to the requirement of the package-on-package, and are not limited herein.

Exemplarily, as shown in FIG. 12, a schematic structural diagram of another kind of pre-package provided for the embodiment of the present disclosure is shown. Referring to FIG. 12, the pre-package includes a chip 11, and first connectors 13 are located at two opposite sides of the chip 11; 16 bonding pads 17 are arranged on one side of the active surface of the chip 11, and the bonding pads 17 are arranged in two rows along the direction parallel to the side edge; the bonding pads 17 and the first connectors 13 are electrically connected through the first redistribution layer 12. The chip 11 is a double-data-rate dynamic random access memory (DDR DRAM), the number of the bonding pads 17, the number of the first redistribution layers 12, and the number of the first connectors 13 (i.e., the first conductor pillars 131) on the active surface of the chip 11 are all equal, about 400 pre-packages at the bottommost layer in the stacked package need to be arranged, and about 100 pre-packages at non-bottommost layer need to be arranged; the diameter of the first conductive post (or column) 131 is greater than or equal to 25 μm, and the pitch is greater than or equal to 40 μm; the minimum line width/line pitch of the first redistribution layer 12 is 5 μm.

In some embodiments, the chip includes at least one of a memory chip, a computing chip, a communication chip, a sense chip, and a power chip.

Illustratively, as shown in FIGS. 7-11, the chips 11 in the pre-package are two Dynamic Random Access Memories (DRAMs); as shown in FIG. 12, the chip 11 in the pre-package is a double data rate dynamic random access memory (DDR DRAM); the embodiments of the present disclosure do not limit the type, number, and capacity of packaged chips, and are applicable to all chips in the technical field.

In some embodiments, as shown in FIG. 1-2, the first connectors 13 of two adjacent pre-packages 10 are disposed at the same position.

For example, as shown in FIG. 1-2, in the stacking interconnection direction, the first connecting bodies 13 of two adjacent pre-package bodies 10 are arranged at the same position, and are both arranged in the gap between two chips 11, so that the two pre-package bodies 10 can be interconnected through the respective first redistribution layer 12 and the first connectors 13 therebetween; compared with the scheme that the arrangement positions of the first connectors 13 in the two adjacent pre-packages 10 are inconsistent, the length of the first redistribution layer 12 is further shortened, and therefore the electrical performance is improved.

On the basis of the foregoing embodiments, embodiments of the present disclosure further provide a method for manufacturing a stacked package, which is used to manufacture any of the foregoing stacked packages, and has corresponding beneficial effects, and in order to avoid repeated descriptions, details are not repeated herein.

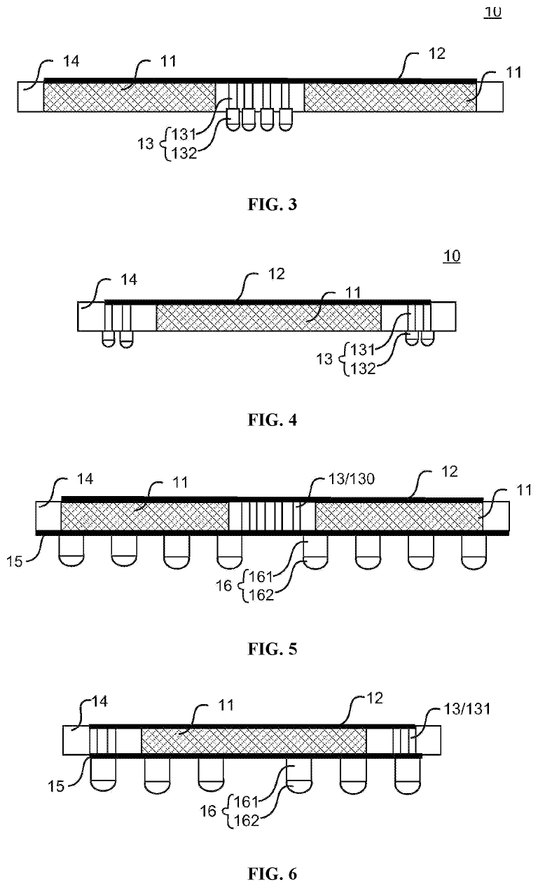

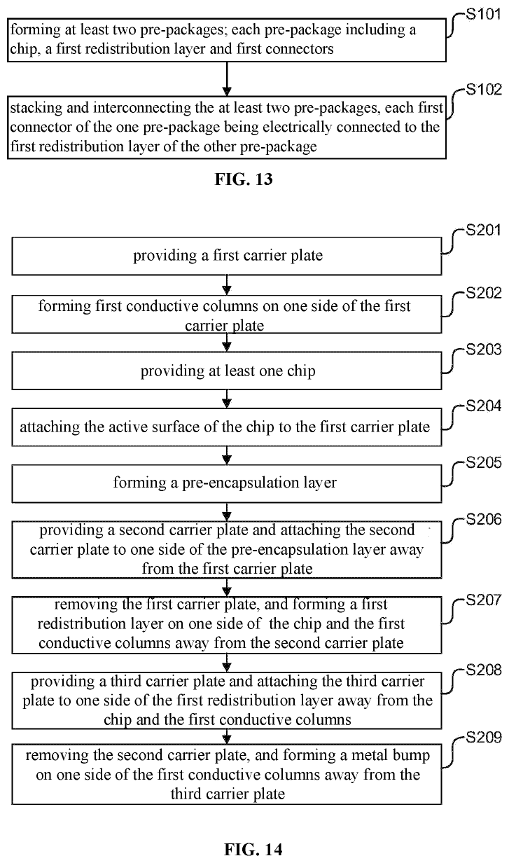

FIG. 13 is a schematic flow chart of a method for manufacturing a package-on-package according to an embodiment of the disclosure. Referring to FIG. 3, the method for manufacturing the package-on-package includes:
and S101, forming at least two pre-packages.

With reference to FIG. 1-2, each pre-package 10 includes a chip 11, a first redistribution layer 12, and first connectors 13; in the stacking/interconnecting direction, the first redistribution layer 12 is located on the active surface side of the chip 11, and the first connectors 13 are located on the same side of the first redistribution layer 12 as the chip 11; in any of one or more directions perpendicular to the stacking/interconnecting direction (e.g., a first predetermined direction X in the figure), at least some of the first connectors 13 are located on at least one edge side of the chip 11, and each first connector 13 is electrically connected to the chip 11 through the first redistribution layer 12.

The chip 11 includes, but is not limited to, a memory chip, a computing chip, a sensing chip, a communication chip, a sensing chip, and a power chip. The first redistribution layer 12 is prepared by an electroplating or deposition process, and the material of the first redistribution layer 12 may be at least one of copper, aluminum, silver, gold, and titanium. A first connector 13 may include a metal column or a metal block made of a metal material, such as a copper column, an aluminum column, a silver column, or the like, or may be a column made of other conductive materials. The first connectors 13 and the first redistribution layer 12 may be formed of the same material, or may be formed of different materials.
S102, at least two pre-package stacks are interconnected.

With reference to FIG. 1-2, an active surface of one pre-package 10 of two adjacent pre-packages 10 is opposite to a passive surface of another pre-package 10, and the first connectors 13 of one pre-package 10 are electrically connected to the first redistribution layer 12 of another pre-package 10.

Specifically, the pre-packages 10 formed in S110 are sequentially connected layer by layer in an overlapping manner, and the first connectors 13 of the pre-packaged body 10 located above are electrically connected to the first redistribution layer 12 of the pre-packaged body 10 located below; since the first redistribution layer 12 is located on one side of the active surface of the chip 11, the passive surface of the upper pre-package 10 is opposite to the active surface of the lower pre-package 10; in this way, the interconnection of two adjacent pre-packages is realized in the upper pre-package 10 by the first redistribution layer 12 and the first connection 13 and the first redistribution layer 12 of the lower pre-package.

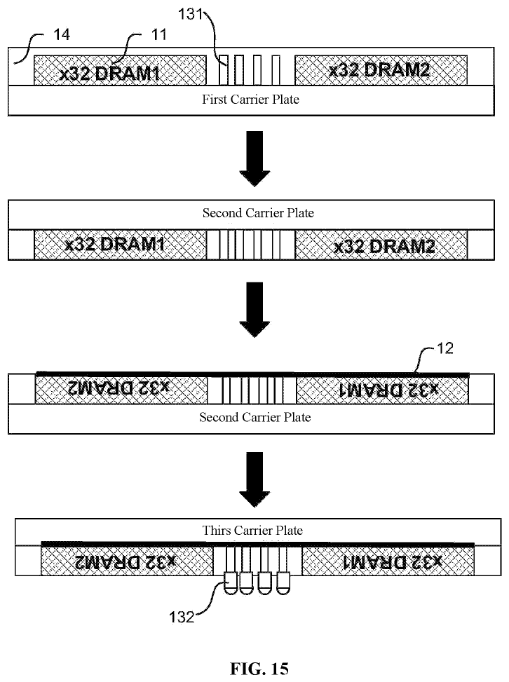

In some embodiments, as shown in FIGS. 14 to 15, FIG. 14 is a schematic detailed flowchart of “forming a pre-package” provided in an embodiment of the present disclosure, and FIG. 15 is a schematic structural diagram corresponding to each step of “forming a pre-package”. Referring to FIGS. 14 and 15, “forming a pre-package” includes:
s201, providing a first carrier plate.
S202, forming a first conductor pillar on one side of the first carrier plate.

The first conductive pillar 131 may be formed by an electroplating process, or may be formed by any process known to those skilled in the art, which is not limited herein. The first conductive pillar 131 may be at least one of copper, aluminum, silver, gold, and titanium.

Illustratively, the first conductor pillar is prepared by an electroplating process, specifically: depositing a Light-To-Heat Conversion Layer (LTHC) Ink, a polymer layer (such as polyimide), a seed layer (including at least one of copper and titanium), and a photoresist layer on a side surface of the first carrier in sequence, placing a first mask layer for patterning the photoresist layer above the photoresist layer To form a blind via penetrating through the photoresist layer, forming a first conductor pillar in the blind via by an electroplating process, removing the photoresist layer, and removing the residual seed layer by etching.
S203, providing at least one chip.

FIG. 15 only exemplarily shows two chips 11, and the chip type is a Dynamic Random Access Memory (DRAM), but does not constitute a limitation on the method for manufacturing the package-on-package provided by the embodiment of the present disclosure. In other embodiments, the number and type of chips may be flexibly set according to requirements, and are not limited herein.
S204, attaching the active surface of the chip and the first carrier plate.

Specifically, the chip 11 is attached to a first carrier by using an adhesive, and the active surface of the chip 11 is opposite to the first carrier; the chip 11 and the first conductive posts 131 are located on the same side of the first carrier plate.
And S205, forming a pre-encapsulation layer.

Specifically, the chip 11 and the first conductor pillar 131 are plastically molded by using an insulating material (e.g., epoxy resin) to form a encapsulation layer 14; the pre-encapsulation layer 14 covers the chip 11, the first conductor pillar 131 and the surface of the first carrier plate facing the chip 11 and the first conductor pillar 131; then, the pre-encapsulation layer 14 is thinned by grinding until the surface of the first conductive posts 131 on the side of the pre-encapsulation layer 14 away from the first carrier plate is exposed; in this manner, the first conductor pillar 131 is filled in and penetrates the pre-encapsulation layer 14.
S206, providing a second carrier plate and attaching the second carrier plate to one side of the pre-encapsulation layer, which is away from the first carrier plate.
And S207, removing the first carrier plate, and forming a first redistribution layer on the chip and one side of the first conductor pillar, which is away from the second carrier plate.

Specifically, when the first carrier sheet is removed, the photothermal conversion layer and the polymer layer deposited on the first carrier sheet when the first conductive posts 131 are prepared are simultaneously removed together with the adhesive used when the chip 11 is attached. After the first carrier is removed, the pre-packaged body is turned upside down, a first redistribution layer 12 is formed on one side of the active surface of the chip 11 by using an electroplating or deposition process, and the first redistribution layer 12 is electrically connected with the bonding pads of the chip 11 and the first conductor pillar 131.
And S208, providing a third carrier plate and attaching the third carrier plate to one side of the first redistribution layer 12, which is away from the chip and the first conductive posts.

Specifically, a third carrier plate is attached to the side where the first redistribution layer 12 is located.
And S209, removing the second carrier plate, and forming a metal bump on one side of the first conductor pillar, which is away from the third carrier plate.

Specifically, after the second carrier is removed, a metal bump 132 is formed at one end of the first conductive pillar 131 away from the first redistribution layer 12 by using an electroplating process; the metal bump 132 is electrically connected to the first conductive pillar 131 and exposed outside the surface of the encapsulation layer 14; the metal bump 132 may be at least one of copper, aluminum, silver, gold, and titanium. Preferably, the first conductive pillar 131 and the metal bump 132 are both made of copper. A cap-shaped solder bump is formed at an end of the metal bump 132 away from the first conductive pillar 131, and the solder bump is selected from solder.

The pre-package formed by the method of the embodiment is suitable for pre-packages other than the bottommost pre-package in the stacked package; with reference to FIG. 1-2, the resulting pre-packages are three pre-packages located at the top and middle layers of the stacked package.

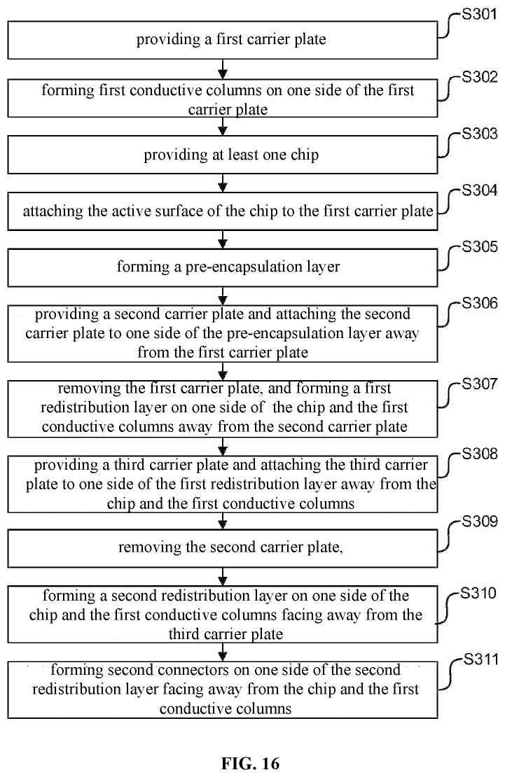

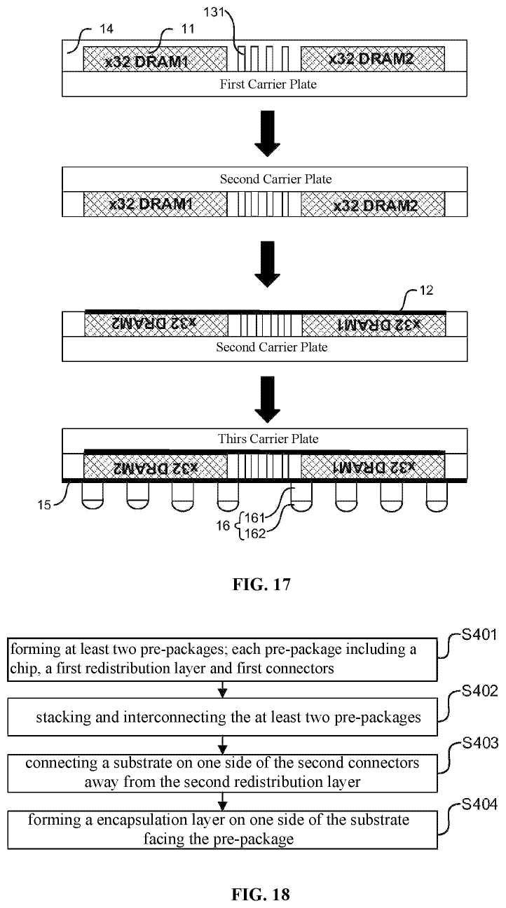

In some embodiments, as shown in FIGS. 16 and 17, FIG. 16 is a schematic detailed flowchart of “forming a pre-package for external connection” provided in an embodiment of the present disclosure, and FIG. 17 is a schematic structural diagram corresponding to each step of “forming a pre-package for external connection”. Referring to FIGS. 16 and 17, “forming a pre-package for external connection” includes:
s301, providing a first carrier plate.
S302, forming a first conductor pillar on one side of the first carrier plate.
S303, providing at least one chip.
S304, attaching the active surface of the chip to the first carrier plate; the chip and the first conductor pillar are located on the same side of the first carrier plate.
And S305, forming a pre-encapsulation layer.

The pre-encapsulation layer coats the chip, the first conductive columns and the surface, facing the chip and the first conductor column, of the first carrier plate, and the first conductor columns extend through the pre-encapsulation layer.
S306, providing a second carrier plate and attaching the second carrier plate to the side of the pre-encapsulation layer departing from the first carrier plate.
S307, removing the first carrier plate, and forming a first redistribution layer on the chip and one side, away from the second carrier plate, of the first conductor column.

Wherein the redistribution layer is electrically connected to the chip and the first conductive posts.
And S308, providing a third carrier plate and attaching the third carrier plate to the side, away from the chip and the first conductor pillar, of the first heavy wiring layer.
309. And removing the second carrier plate.

The pre-package for external connection refers to the pre-package located at the bottommost part of the stacked package in the stacking interconnection direction, and other pre-packages are not stacked below the pre-package, but other components are externally connected, and the structure of the pre-package is mostly the same as that of the pre-package located above the pre-package, except that: (1) a first connector 13 of the pre-package for external connection only comprises the first conductor columns 131 extend through the encapsulation layer 14, and no metal bump 132 is arranged; (2) A second redistribution layer 15 is formed on the side of the pre-package for external connection facing away from the first redistribution layer 12, second connectors 16 are formed on the side of the second redistribution layer 15 facing away from the first conductive posts 131, and the second redistribution layer 15 is electrically connected to the first conductive posts 131 and the second connectors 16.

The steps of forming the pre-package for external connection are the same as the steps of forming the pre-package, and the steps of forming the pre-package are performed until the second carrier is removed, that is, S301 to S309 are the same as S201 to S208, which may be referred to as S201 to S208, and are not described again.

And S310, forming a second redistribution layer on the chip and one side of the first conductor pillar, which is away from the third carrier plate.

Specifically, after the second carrier is removed, a second redistribution layer 15 is formed on the side of the pre-package body away from the first redistribution layer 12 by using an electroplating or deposition process, and the second redistribution layer 15 is electrically connected with the first conductor pillar 131 of the pre-package body; the second redistribution layer 15 may be made of at least one of copper, aluminum, silver, gold, and titanium.
311. Second connectors are formed on a side of the second redistribution layer facing away from the chip and the first conductive posts.

The second connectors 16 is electrically connected to the second redistribution layer 15 for externally connecting other components, such as a substrate, a printed circuit board, or a processor.

Illustratively, as shown in FIG. 17, a second connector 16 includes a second conductive post (or column) 161 and a solder bump 162; a second conductive post 161 is formed on the side of the second redistribution layer 15 facing away from the pre-package body by an electroplating process, and a solder bump 162 is formed on the side of the second conductive post facing away from the second redistribution layer 15.

It should be noted that FIG. 17 only illustrates an arrangement form of the second connectors 16 by way of example, and does not limit the method for manufacturing the package-on-package provided in the embodiment of the present disclosure. In other embodiments, the second connectors 16 may be provided in other forms known to those skilled in the art, such as solder balls, but not limited thereto.

In some embodiments, as shown in FIG. 18, a schematic flow chart of another method for manufacturing a package-on-package according to embodiments of the present disclosure is provided. As shown in FIG. 18, after interconnecting at least two pre-package stacks, the method of making further comprises:
and S403, connecting the substrate on the side of the second connectors, which is away from the second redistribution layer.

With reference to FIG. 1-2, in the first predetermined direction X, the length of the substrate 20 is greater than the length of the pre-package 10; the first predetermined direction X can be any direction perpendicular to the stacking/interconnecting direction. Thus, the substrate 20 is larger than the pre-package 10, and serves as a substrate for the package layer 30 to support the package layer 30.
S404, forming a encapsulation layer on one side of the substrate facing the pre-package.

In conjunction with FIG. 1-2, the encapsulation layer 30 covers all the pre-packages 10 and the surface of the substrate 20 facing the pre-packages 10.

The encapsulating layer 30 may be a prepreg, and covers all surfaces of the pre-package 10 and the substrate 20 facing the pre-package 10, where the prepreg includes one or a combination of epoxy resin, polyethylene, polypropylene, polyolefin, polyamide, polyurethane, and the like. The encapsulating layer 30 may also be made of liquid or powdered epoxy resin, which not only covers all the surfaces of the pre-packaged bodies 10 and the substrate 20 facing the pre-packaged bodies 10, but also fills all the gaps between the pre-packaged bodies 10 and the substrate 20.

On the basis of the above embodiment, the embodiment of the present disclosure further provides an electronic device. The electronic device includes: any of the above stacked packages has corresponding advantages, and is not limited herein to avoid repeated descriptions.

The electronic devices include, but are not limited to, portable devices (such as laptop computers), mobile communication devices (such as smart phones and tablets), and computer servers.

It is noted that, in this document, relational terms such as “first” and “second,” and the like, are used solely to distinguish one entity or action from another entity or action without necessarily requiring or implying any actual such relationship or order between such entities or actions. Also, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. Without further limitation, an element defined by the phrase “comprising a . . . ” does not exclude the presence of another identical element in a process, method, article, or apparatus that comprises the element.

The foregoing are merely exemplary embodiments of the present disclosure, which enable those skilled in the art to understand or practice the present disclosure. Various modifications to these embodiments will be readily apparent to those skilled in the art, and the generic principles defined herein may be applied to other embodiments without departing from the spirit or scope of the disclosure. Thus, the present disclosure is not intended to be limited to the embodiments shown herein but is to be accorded the widest scope consistent with the principles and novel features disclosed herein.

We claim:

1. A package-on-package, comprising:
at least two pre-packages; each pre-package the at least two pre-packages including at least one chip, a first redistribution layer and first connectors, each chip having an active side and a passive side, each respective pre-package having an active side corresponding to the active side of each the at least one chip in the respective pre-package, and a passive side opposite to the active side of the respective pre-package; wherein:
the at least two pre-packages are stacked and interconnected, whereby the active side of one pre-package of two adjacent pre-packages faces the passive side of the other pre-package of the two adjacent pre-packages, and the first connectors of the one pre-package of the two adjacent pre-packages are electrically connected with the first redistribution layer of the other pre-package of the two adjacent pre-packages;
the first redistribution layer in the respective pre-package is disposed on the active side of the respective pre-package, the first connectors and the at least one chip in the respective pre-package are positioned on a same side of the first redistribution layer;
at least some of first connectors in the respective pre-package are located on at least one edge side of a respective chip of the at least one chip in the respective pre-package, and each of the at least some of first connectors is electrically connected with the respective chip through the first redistribution layer.

2. The package-on-package of claim 1, wherein the pre-package further comprises: a encapsulation layer that encapsulates the chip and the first connectors; each first connector includes a first conductive post;
the first conductor columns extend through the pre-encapsulation layer and is connected with the first redistribution layer of the pre-package.

3. The package-on-package of claim 2, wherein the each first connector further comprises: a metal bump; the metal bump is electrically connected with the first conductor pillar and exposed outside the surface of the pre-encapsulation layer; the metal bump is electrically connected with the first redistribution layer of the adjacent pre-package.

4. The package-on-package of claim 2, wherein the pre-package for external connection further comprises a second redistribution layer and second connectors;
the second redistribution layer is located on one side, away from the first redistribution layer, of the chip and the first conductor column, the second connectors are located on one side, away from the chip and the first conductor column, of the second redistribution layer, the second redistribution layer is electrically connected with the first conductor columns and the second connectors, and the second connectors are used for externally connecting other components.

5. The package-on-package of claim 4, further comprising: a substrate and an encapsulation layer;
the substrate is positioned on one side, away from the second redistribution layer, of the second connectors; in a first preset direction, the length of the substrate is greater than that of the pre-package; the first preset direction is any direction perpendicular to the stacking/interconnecting direction;
the encapsulation layer is positioned on one side of the substrate facing the pre-package, and the encapsulation layer covers all the pre-packages which are connected in a stacked mode and the surface of the substrate facing the pre-packages.

6. The package-on-package of claim 5, wherein a second connector comprises a second conductive post and a solder bump, the second conductive post and the solder bump being electrically connected;
the second conductor pillar is located on one side of the second redistribution layer, which is away from the chip and the first connectors, and is electrically connected with the second redistribution layer;
the welding block is positioned on one side, away from the second redistribution layer, of the second conductor columns and used for connecting the substrate.

7. The package-on-package of claim 5, further comprising: third connectors;
third connectors are positioned on one side of the substrate facing away from the second connector, and is used for connecting other components.

8. The package-on-package of any one of claim 1, wherein the pre-package further comprises: bonding pads;
the bonding pads are located on one side of the active surface of the chip, the bonding pads are distributed in an area of the chip close to the first connectors, and the bonding pads are electrically connected with the first connectors through the first redistribution layer.

9. The package-on-package of claim 1, wherein the chip comprises at least one of a memory chip, a computing chip, a communication chip, a sense chip, and a power chip.

10. The package-on-package of claim 1, wherein the first connectors of two adjacent pre-packages are disposed at corresponding positions.

11. A method for forming a Package-on-package (PAC), comprising:
forming at least two pre-packages; each pre-package including a chip, a first redistribution layer and first connectors; and
stacking and interconnecting the at least two pre-packages, whereby an active surface of one pre-package in two adjacent pre-packages is opposite to a passive surface of the other pre-package of the two adjacent pre-packages, and each first connector of the one pre-package is electrically connected with the first redistribution layer of the other pre-package;
wherein, in the stacking/interconnecting direction, the first redistribution layer is positioned on an active side of the chip, and the first connectors and the chip are positioned on a same side of the first redistribution layer; in any direction perpendicular to the stacking/interconnecting direction, at least some of the first connectors are located on at least one edge side of a chip and is electrically connected with the chip through the first redistribution layer.

12. The method according to claim 11, wherein forming the pre-package comprises:
providing a first carrier plate;
forming first conductor columns on one side of the first carrier plate;
providing at least one chip;
attaching the active surface of the chip to the first carrier plate; the chip and the first conductor columns are positioned on the same side of the first carrier plate;
forming a pre-encapsulation layer, wherein the pre-encapsulation layer coats the chip, the first conductor pillar and the surface of the first carrier plate facing the chip and the first conductor pillar, and the first conductor pillar is filled in and penetrates through the pre-encapsulation layer;
providing a second carrier plate and attaching the second carrier plate to one side of the pre-encapsulation layer away from the first carrier plate;
removing the first carrier plate, and forming a first redistribution layer on one side of the chip and the first conductive columns away from the second carrier plate, wherein the redistribution layer is electrically connected with the chip and the first conductive post;
providing a third carrier plate and attaching the third carrier plate to one side of the first redistribution layer away from the chip and the first conductor columns;
and removing the second carrier plate, and forming a metal bump on one side of the first conductive columns away from the third carrier plate.

13. The method according to claim 12, wherein forming a pre-package for external connection includes:
executing the step of forming the pre-package until the second carrier plate is removed;
forming a second redistribution layer on one side of the chip and the first conductive columns facing away from the third carrier plate; and
forming second connectors on one side of the second redistribution layer facing away from the chip and the first conductor pillar.

14. The method of claim 13, wherein after said interconnecting said at least two pre-package stacks, said method further comprises:
connecting a substrate on one side of the second connectors away from the second redistribution layer; in a first preset direction, the length of the substrate is greater than that of the pre-package; the first preset direction is any direction perpendicular to the stacking/interconnecting direction;
forming a encapsulation layer on one side of the substrate facing the pre-package; the encapsulation layer covers all the pre-packages and the surface of the substrate facing the pre-packages, which are connected in a stacked mode.

15. An electronic device, comprising: the package-on-package of claim 1.
